(19) United States
(12) Patent Application Publication
(10) Pub. No.: US 2024/0105624 A1
(43) Pub. Date: Mar. 28, 2024

(54) SEMICONDUCTOR DEVICE

(71) Applicant: FUJI ELECTRIC CO., LTD., Kanagawa (JP)

(72) Inventor: Shinichiro MATSUNAGA, Matsumoto-city (JP)

(21) Appl. No.: 18/356,220

(22) Filed: Jul. 21, 2023

(30) Foreign Application Priority Data
Sep. 22, 2022 (JP) 2022-151160

(51) Int. Cl. H01L 23/535; H01L 29/06; H01L 29/10; H01L 29/16; H01L 29/78

(52) U.S. Cl. CPC H01L 23/535; H01L 29/063; H01L 29/0696; H01L 29/1095; H01L 29/1608; H01L 29/7813

(57) ABSTRACT

Provided is a semiconductor device which includes: a semiconductor substrate containing silicon carbide; a plurality of first gate trench portions arranged side by side in a first direction; a first mesa portion sandwiched between two of the first gate trench portions; and a mesa facing region not sandwiched between two of the first gate trench portions in the first direction and arranged to face the first mesa portion in a second direction different from the first direction, and in which a contact hole is not provided in an interlayer dielectric film above the first mesa portion, and a source region is provided to extend from the first mesa portion to the mesa facing region and is connected to an upper-surface electrode via the contact hole.

The contents of the following patent application (s) are incorporated herein by reference: NO. 2022-151160 filed in JP on Sep. 22, 2022

### BACKGROUND

### 1. Technical Field

The present invention relates to a semiconductor device.

### 2. Related Art

Conventionally, there has been known a semiconductor device which includes a plurality of trench gates and in which a source region of an N type or the like is formed in a mesa portion sandwiched between two trench gates (for example, see Patent Document 1). An interlayer dielectric film which insulates an upper-surface electrode and a semiconductor substrate from each other is provided above the semiconductor substrate. A contact hole is formed in the interlayer dielectric film above the mesa portion, and the mesa portion and a source electrode are connected.
Patent Document 1: Japanese patent No. 3329707

### BRIEF DESCRIPTION OF THE DRAWINGS

FIG. 1 is a top view illustrating an example of a semiconductor device 100 according to one embodiment of the present invention.

FIG. 2 illustrates an example of an A-A cross section in FIG. 1.

FIG. 3 is a view illustrating an example of a B-B cross section in FIG. 1.

FIG. 4 is a view illustrating an example of a C-C cross section in FIG. 1.

FIG. 5 is a view illustrating an example of a D-D cross section in FIG. 1.

FIG. 6 is an enlarged top view of a first gate trench portion 41 and a first mesa portion 61.

FIG. 7 is a top view illustrating a different example of the semiconductor device 100 according to one embodiment of the present invention.

FIG. 8 is a view illustrating an example of a B-B cross section in FIG. 7.

FIG. 9 is a view illustrating an example of an E-E cross section in FIG. 7.

FIG. 10 is a view illustrating an example of an F-F cross section in FIG. 7.

FIG. 11 is a view illustrating a different example of the B-B cross section in FIG. 7.

FIG. 12 is a view illustrating a different example of the E-E cross section in FIG. 7.

FIG. 13 is a view illustrating a different example of the F-F cross section in FIG. 7.

FIG. 14 is a top view illustrating a semiconductor device 200 according to a comparative example.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

Unless otherwise stated, SI unit system is used as unit system herein. Although a unit of length may be expressed in cm, calculations may be carried out after conversion to meters (m). In the present specification, one side of a direction parallel to a depth direction of a semiconductor substrate is referred to as “upper”, and the other side is referred to as “lower”. One of two main surfaces of a substrate, a layer, or other members is referred to as an “upper surface”, and the other surface is referred to as a “lower surface”. “Upper” and “lower” directions are not limited to a direction of gravity, or a direction in which a semiconductor device is mounted.

As used herein, technical matters may be described with orthogonal coordinate axes consisting of an X axis, a Y axis, and a Z axis. The orthogonal coordinate axes are merely for specifying relative positions of components, and are thus not for limiting to a specific direction. For example, the Z axis is not limited to represent a height direction with respect to the ground. Note that a +Z axis direction and a −Z axis direction are directions opposite to each other. When a direction is referred to as a “Z axis direction” without these “−F” and “−” signs, it means the Z axis direction is parallel to +Z and −Z axes.

In the present specification, orthogonal axes parallel to an upper surface and lower surface of a semiconductor substrate are referred to as the X axis and the Y axis. Further, an axis perpendicular to the upper surface and the lower surface of the semiconductor substrate is referred to as the Z axis. As used herein, a direction of the Z axis may be referred to as a depth direction. Further, in the present specification, a direction parallel to the upper surface and the lower surface of the semiconductor substrate may be referred to as a horizontal direction, including the X axis direction and the Y axis direction. In the present specification, an upper surface side of the semiconductor substrate refers to a region from the center to the upper surface of the semiconductor substrate in the depth direction. A lower surface side of the semiconductor substrate refers to a region from the center to the lower surface of the semiconductor substrate in the depth direction.

As used herein, phrases such as “same” or “equal” may be used even when there is an error caused due to a variation in a fabrication step or the like. This error is within a range of 10% or less, for example. In the present specification, the description of a direction such as “vertical”, “parallel”, or “along” may be used even when there is an error caused due to a variation in manufacturing or the like. The error is 5 degrees or smaller, for example.

In the present specification, a conductivity type of a doping region where doping has been carried out with an impurity is described as a P type or an N type. The N type is an example of a first conductivity type, and the P type is an example of a second conductivity type. In the present specification, doping means introducing the donor or the acceptor into the semiconductor substrate and turning it into a semiconductor showing a conductivity type of the N type, or a semiconductor showing a conductivity type of the P type. In the present specification, a description of a P+ type or an N+ type means a higher doping concentration than that of the P type or the N type, and a description of a P− type or an N− type means a lower doping concentration than that of the P type or the N type.

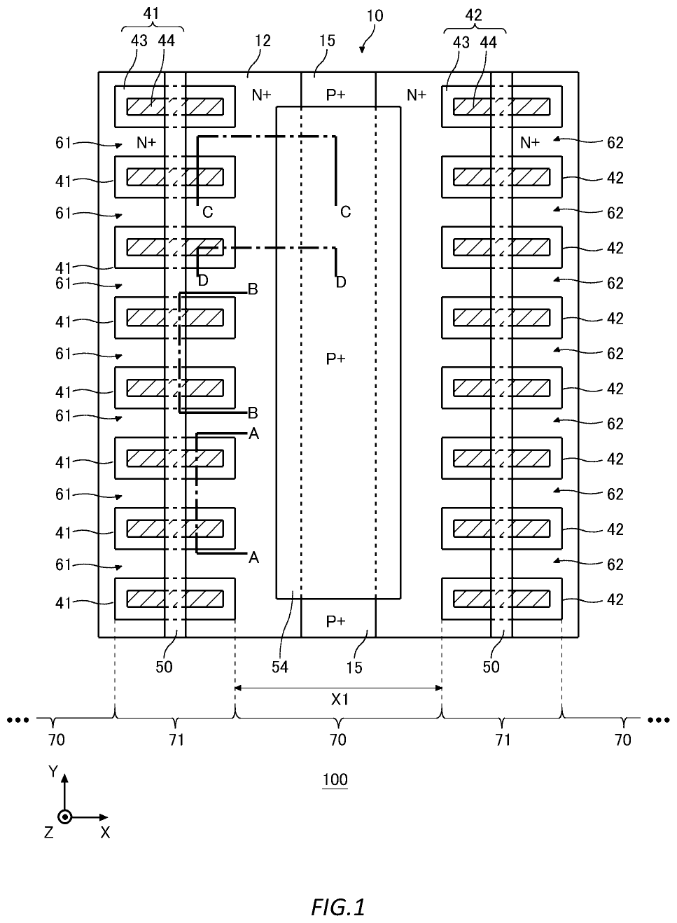

FIG. 1 is a top view illustrating an example of a semiconductor device 100 according to one embodiment of the present invention. The semiconductor device 100 is a semiconductor chip on which a transistor element such as a MOSFET is formed. The semiconductor device 100 includes a semiconductor substrate 10 on which a transistor element is formed. The semiconductor substrate 10 of this example is a substrate containing silicon carbide (SiC). As an example, the semiconductor substrate 10 is a silicon carbide substrate entirely formed of silicon carbide except for a trace amount of impurities. FIG. 1 illustrates a partial region of the upper surface of the semiconductor substrate 10. A gate pad or the like to which a gate voltage is applied is provided in the semiconductor substrate 10, but is omitted in FIG. 1. In FIG. 1, the positions of some members of the semiconductor device 100 are projected on the upper surface of the semiconductor substrate 10. In the present specification, observation in a state where the position of each member is projected on a plane parallel to the upper surface of the semiconductor substrate 10 may be referred to as a top view.

The semiconductor device 100 includes a plurality of first gate trench portions 41, one or more first mesa portions 61, a source region 12 of the N+ type, a gate runner 50, a mesa facing region 70, and a contact hole 54. The semiconductor device 100 may further include a contact region 15 of the P+ type. The semiconductor device 100 may further include a plurality of second gate trench portions 42 and one or more second mesa portions 62. The gate runner 50 is connected to the above-described gate pad and transmits a gate voltage.

The plurality of first gate trench portions 41 are arranged side by side in a first direction (a Y axis direction in the example of FIG. 1) on the upper surface of the semiconductor substrate 10. Each of the first gate trench portions 41 is provided from the upper surface of the semiconductor substrate 10 to the inside of the semiconductor substrate 10. Each of the first gate trench portions 41 includes a gate dielectric film 43 and a gate electrode 44. The gate dielectric film 43 covers the inner wall of the groove-shaped first gate trench portion 41. The gate dielectric film 43 is, for example, a film formed by oxidizing or nitriding the inner wall of the first gate trench portion 41. The gate dielectric film may be formed by depositing an oxide film or a nitride film instead of by oxidizing or nitriding the inner wall.

The gate electrode 44 is enclosed by the gate dielectric film 43. The gate dielectric film 43 electrically insulates the gate electrode 44 and the semiconductor substrate 10 from each other. The gate electrode 44 is connected to the gate runner 50, and a gate voltage is applied thereto. The gate electrode 44 is formed by, for example, depositing polysilicon doped with impurities in a region enclosed by the gate dielectric film 43.

The plurality of first gate trench portions 41 are provided separately from each other. The plurality of first gate trench portions 41 of this example have linear shapes parallel to each other on the upper surface of the semiconductor substrate 10.

In the semiconductor substrate 10, a region sandwiched between two first gate trench portions 41 in the Y axis direction is referred to as a first mesa portion 61. In the semiconductor device 100 of this example, a plurality of first mesa portions 61 are arranged in the Y axis direction. The first mesa portion 61 is provided with a source region 12 of the N+ type. A base region of the P type is provided below the source region 12, but is omitted in FIG. 1. A drift region of the N-type is provided below the base region, but is omitted in FIG. 1. The first gate trench portion 41 is provided penetrating the base region. When a predetermined ON voltage is applied to the gate electrode 44, the surface layer of the base region in contact with the first gate trench portion 41 is inverted to the N type, and a channel connecting the source region 12 and the drift region is formed. Accordingly, the semiconductor device 100 is turned on, and a main current flows.

The source region 12 is connected to an upper-surface electrode (for example, a source electrode) provided above the semiconductor substrate 10. An interlayer dielectric film is provided between the semiconductor substrate 10 and the upper-surface electrode. In this case, a structure is conceivable in which a contact hole is formed in the interlayer dielectric film above the first mesa portion 61 to connect the source region 12 and the upper-surface electrode. However, when the semiconductor device 100 is miniaturized to reduce the width of the first mesa portion 61 in the Y axis direction, it is difficult to form the contact hole in the interlayer dielectric film above the first mesa portion 61.

For example, when the contact hole exposes the gate electrode 44, the source electrode (upper-surface electrode) and the gate electrode 44 come into contact with each other. In order to avoid the contact between the source electrode and the gate electrode 44, the contact hole is arranged away from the first gate trench portion 41 by a predetermined distance. The lower limit value of the distance is determined by a variation in mask position or the like. In addition, the lower limit value of the width of the contact hole is determined by the resolution of a manufacturing device or the like. The width of the first mesa portion 61 is designed to be larger than the sum of the above-described distance and the width of the contact hole. For this reason, when the contact hole is provided above the first mesa portion 61, the width of the first mesa portion 61 is limited by the resolution of the manufacturing device, a variation in mask position, or the like.

As described above, when the contact hole is formed in the interlayer dielectric film above the first mesa portion 61, there is a limit to miniaturization of the first mesa portion 61. When the semiconductor substrate 10 is silicon carbide, the sheet resistance of the semiconductor substrate 10 is relatively high, and the resistance of the channel to be formed tends to be high, and thus it is preferable to improve the channel density. However, when the contact hole is formed in the interlayer dielectric film above the first mesa portion 61, it is difficult to miniaturize the first mesa portion 61, and it is difficult to improve the channel density.

In the semiconductor device 100 of this example, no contact hole is provided in the interlayer dielectric film above the first mesa portion 61. The source region 12 is provided to extend from the first mesa portion 61 to the mesa facing region 70, and is connected to the upper-surface electrode via the contact hole 54. The mesa facing region 70 is a region that is not sandwiched between two first gate trench portions 41 in the first direction (the Y axis direction in this example) and is arranged to face the first mesa portion 61 in the second direction (the X axis direction in this example) different from the first direction (the Y axis direction in this example). The first direction and the second direction may be directions orthogonal to each other.

Since the contact hole 54 is not provided in the first mesa portion 61, the first mesa portion 61 can be easily miniaturized. Therefore, the channel density of the semiconductor device 100 can be easily improved. Since the mesa facing region 70 is not sandwiched between the first gate trench portions 41 in the Y axis direction, the width of the mesa facing region 70 in the Y axis direction can be made larger than the width of one first mesa portion 61. For this reason, the contact hole 54 can be easily provided in the mesa facing region 70. Accordingly, it is possible to achieve both miniaturization of the first mesa portion 61 and electrical connection between the first mesa portion 61 and the upper-surface electrode.

In this example, the source regions 12 of the plurality of first mesa portions 61 are connected to each other in the mesa facing region 70. The source regions 12 of the respective first mesa portions 61 extend from the first mesa portion 61 to the mesa facing region 70 in the X axis direction, and further extend in the mesa facing region 70 in the Y axis direction to be connected to each other. The contact hole 54 may expose the source region 12. Accordingly, the upper-surface electrode and the source region 12 can be connected. In another example, the source region 12 may be electrically connected to a wire of polysilicon or the like in the mesa facing region 70, and the contact hole 54 may expose the wire. Also in this case, the upper-surface electrode and the source region 12 can be electrically connected.

The contact hole 54 of this example is arranged to face the plurality of first mesa portions 61 in the X axis direction. That is, the contact hole 54 is continuously provided from a position facing the first mesa portion 61 arranged at one end in the Y axis direction to a position facing another first mesa portion 61 arranged at the other end in the Y axis direction among the plurality of first mesa portions 61. The contact holes 54 may be discretely arranged in the Y axis direction. Each contact hole 54 may be arranged to face one first mesa portion 61, or may be arranged to face two or more first mesa portions 61. The contact hole 54 may have a longer side in the Y axis direction. That is, the length of the contact hole 54 in the Y axis direction may be larger than the length in the X axis direction. Accordingly, it is easy to arrange one contact hole 54 to face the plurality of first mesa portions 61.

All the first mesa portions 61 may be arranged to face any of the contact holes 54 in the X axis direction. Accordingly, a distance between each of the first mesa portions 61 and the upper-surface electrode can be shortened, and an electrical resistance can be reduced. In addition, the distance between each of the first mesa portions 61 and the upper-surface electrode can be made uniform.

The contact region 15 is provided on the upper surface of the mesa facing region 70 of this example. The contact hole 54 exposes at least a part of the contact region 15. In FIG. 1, the contact region 15 exposed by the contact hole 54 is indicated by a broken line. Accordingly, the upper-surface electrode and the contact region 15 are connected via the contact hole 54. The contact region 15 is connected to a base region provided in the first mesa portion 61. Accordingly, the base region and the upper-surface electrode can be electrically connected. The contact region 15 is a region of the P+ type having a higher concentration than the base region. Accordingly, a contact resistance between the upper-surface electrode and the contact region 15 can be reduced.

In this example, the base regions of the plurality of first mesa portions 61 are connected to the contact region 15 in the mesa facing region 70. The base regions of the plurality of first mesa portions 61 may be connected to each other in the mesa facing region 70. The base region of each of the first mesa portions 61 extends from the first mesa portion 61 to the contact region 15 in the X axis direction. The base region is provided below the source region 12. The base region may not be exposed on the upper surface of the semiconductor substrate 10 in any of the first mesa portion 61 and the mesa facing region 70. In another example, a base region may be provided instead of the contact region 15. In this case, the base region and the upper-surface electrode are connected via the contact hole 54.

The gate runner 50 is provided above the upper surface of the semiconductor substrate 10 to overlap the plurality of first gate trench portions 41. The gate runner 50 of this example extends to have a longer side in the Y axis direction, and intersects with the plurality of first gate trench portions 41. The gate runner 50 is connected to the gate electrode 44 of the first gate trench portion 41 at an intersection portion with each of the first gate trench portions 41. The gate runner 50 may be a metal wire formed of a metal material such as aluminum, may be a semiconductor runner formed of a semiconductor material such as polysilicon doped with impurities, or may be a laminated wire in which a metal wire and a semiconductor runner are laminated via a dielectric film. When the gate runner 50 is a laminated wire, the metal wire and the semiconductor runner are connected by a contact hole formed in the dielectric film.

The semiconductor device 100 of this example includes a plurality of second gate trench portions 42 and one or more second mesa portions 62. The plurality of second gate trench portions 42 are arranged on the opposite side of the plurality of first gate trench portions 41 with the mesa facing region 70 interposed therebetween. That is, the region provided with the plurality of second gate trench portions 42 faces the region provided with the plurality of first gate trench portions 41 in the X axis direction, and the mesa facing region 70 is arranged between the region provided with the plurality of second gate trench portions 42 and the region provided with the plurality of first gate trench portions 41.

The structure of each of the second gate trench portions 42 is the same as that of the first gate trench portion 41. The arrangement of the plurality of second gate trench portions 42 is similar to the arrangement of the plurality of first gate trench portions 41. That is, the plurality of second gate trench portions 42 are arranged in the Y axis direction. In the semiconductor substrate 10, the region sandwiched between two second gate trench portions 42 in the Y axis direction is referred to as the second mesa portion 62. In the semiconductor device 100 of this example, the plurality of second mesa portions 62 are arranged in the Y axis direction. The structure of the second mesa portion 62 is similar to the structure of the first mesa portion 61. For example, the second mesa portion 62 is provided with the source region 12 of the N+ type and the base region of the P type. A contact hole is not provided in the interlayer dielectric film above the second mesa portion 62.

In the Y axis direction, an interval between two second gate trench portions 42 may be the same as an interval between two first gate trench portions 41. That is, the width of the second mesa portion 62 in the Y axis direction may be the same as the width of the first mesa portion 61 in the Y axis direction. The second gate trench portion 42 may be arranged to face the first gate trench portion 41 in the X axis direction, may be arranged to face the first mesa portion 61, or may be arranged to face a part of the first gate trench portion 41 and a part of the first mesa portion 61.

The source region 12 of each of the second mesa portions 62 has a structure similar to that of the source region 12 of each of the first mesa portions 61. The source region 12 of the second mesa portion 62 is provided to extend from the second mesa portion 62 to the mesa facing region 70, and is connected to the upper-surface electrode via the contact hole 54. The source region 12 of the second mesa portion 62 and the source region 12 of the first mesa portion 61 may be connected to the upper-surface electrode through the common contact hole 54.

The base region of each of the second mesa portions 62 has a structure similar to that of the base region of each of the first mesa portions 61. The base region of the second mesa portion 62 and the base region of the first mesa portion 61 may be connected to the common contact region 15.

The gate runner 50 is also provided above the plurality of second gate trench portions 42 and the plurality of second mesa portions 62. The gate runner 50 is connected to the gate electrode 44 of each of the second gate trench portions 42.

A region including a plurality of gate trench portions and mesa portions arranged in the Y axis direction is referred to as a channel region 71. As illustrated in FIG. 1, the channel density can be further improved by arranging two channel regions 71 with the mesa facing region 70 interposed therebetween in the X axis direction. The structures of the respective channel regions 71 may be the same as each other. The mesa facing region 70 and the channel region 71 may be alternately arranged on the upper surface of the semiconductor substrate 10 repeatedly twice or more in the X axis direction. That is, one channel region 71 may be sandwiched between two mesa facing regions 70 in the X axis direction. The structures of the respective mesa facing regions 70 may be the same as each other. In this case, the source region 12 of each of the mesa portions is connected to the upper-surface electrode in two mesa facing regions 70 arranged on both sides in the X axis direction. Accordingly, the maximum value of the distance from each position of the mesa portions to the upper-surface electrode can be reduced, and the electrical resistance value can be reduced.

A distance between the plurality of first gate trench portions 41 and the plurality of second gate trench portions 42 in the X axis direction is referred to as X1. That is, a distance between the channel regions 71 in the X axis direction is X1, and the width of the mesa facing region 70 in the X axis direction is X1. As an example, the distance X1 is 2 μm or less. By reducing the distance X1, the proportion occupied by the channel region 71 in the semiconductor substrate 10 can be increased, and the channel density can be further improved. The distance X1 may be 1.5 μm or less or 1 μm or less. The distance X1 has a size with which the contact hole 54 can be stably formed. The size is determined according to the resolution of the manufacturing device or the like. The distance X1 may be 0.5 μm or more, and may be 1 μm or more.

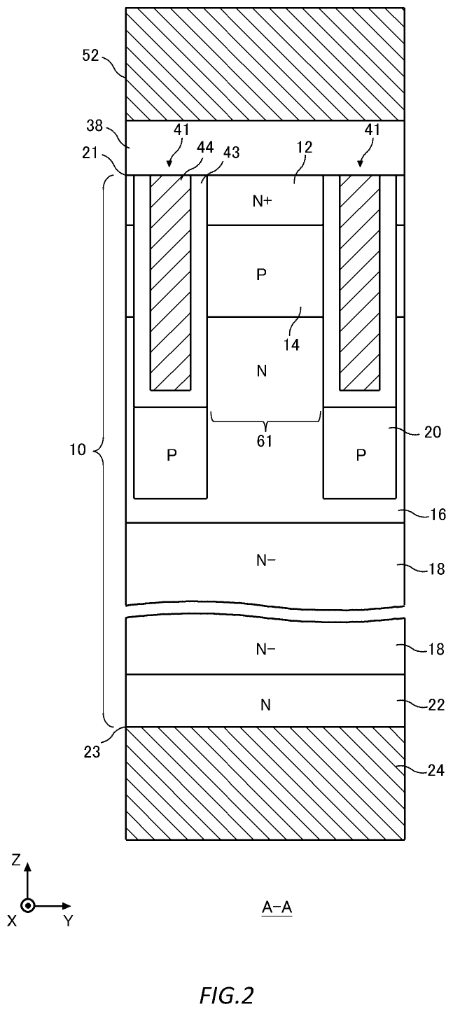

FIG. 2 is a view illustrating an example of an A-A cross section in FIG. 1. The A-A cross section is a YZ plane passing through two first gate trench portions 41 and the first mesa portion 61. The second gate trench portion 42 and the second mesa portion 62 also have a structure similar to that of the first gate trench portion 41 and the first mesa portion 61.

The semiconductor device 100 of this example includes the semiconductor substrate 10, an interlayer dielectric film 38, a source electrode 52, and a drain electrode 24 in the cross section. The source electrode 52 is an example of the upper-surface electrode. The source electrode 52 and the drain electrode 24 are made of a metal material such as aluminum.

The interlayer dielectric film 38 is provided above the upper surface 21 of the semiconductor substrate 10. The interlayer dielectric film 38 is a film including at least one layer of a dielectric film such as silicate glass doped with impurities of boron, phosphorus, or the like, a thermally oxidized film, or other dielectric films. A contact hole is not provided in the interlayer dielectric film 38 above the first mesa portion 61. The source electrode 52 is provided above the interlayer dielectric film 38. The drain electrode 24 is provided on the lower surface 23 of the semiconductor substrate 10.

The semiconductor substrate 10 has a drift region 18 of the N-type arranged between the upper surface 21 and the lower surface 23. In the first mesa portion 61, the source region 12 of the N+ type having a higher doping concentration than that of the drift region 18 is provided between the drift region 18 and the upper surface 21 of the semiconductor substrate 10. In the first mesa portion 61, the source region 12 may be exposed to the upper surface 21 of the semiconductor substrate 10 or may not be exposed. A base region 14 of the P type is provided between the source region 12 and the drift region 18. A high concentration region 16 of the N type having a higher doping concentration than that of the drift region 18 may be provided between the base region 14 and the drift region 18. By providing the high concentration region 16, a resistance of a path through which a main current flows can be reduced.

A drain region 22 of the N type having a doping concentration higher than that of the drift region 18 may be provided between the drift region 18 and the lower surface 23. The drain region 22 is connected to the drain electrode 24. In another example, the drift region 18 may be connected to the drain electrode 24 without providing the drain region 22 in the semiconductor substrate 10.

The plurality of first gate trench portions 41 are provided on the upper surface 21 of the semiconductor substrate 10. Each of the first gate trench portions 41 is provided from the upper surface 21 of the semiconductor substrate 10 to below the base region 14. The first gate trench portion 41 of this example is provided to a depth reaching the high concentration region 16. When the high concentration region 16 is not provided, the first gate trench portion 41 may be provided to a depth reaching the drift region 18. When a predetermined ON voltage is applied to the gate electrode 44, a channel is formed in the surface layer of the base region 14 in contact with the first gate trench portion 41, and a main current flows between the source electrode 52 and the drain electrode 24.

The semiconductor substrate 10 may be provided with a lower end region 20 of the P type in contact with the lower end of the first gate trench portion 41. The lower end region 20 may be provided in a range shallower than the lower end of the high concentration region 16, and may be in contact with the drift region 18. By providing the lower end region 20, it is possible to alleviate the electric field concentration in the vicinity of the lower end of the first gate trench portion 41 and improve the withstand voltage of the semiconductor device 100.

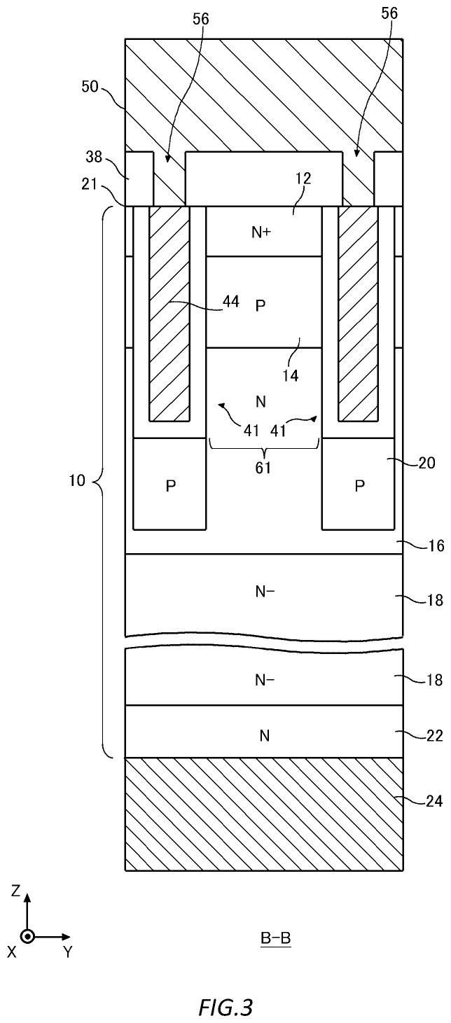

FIG. 3 is a view illustrating an example of a B-B cross section in FIG. 1. The B-B cross section is a YZ plane passing through the gate runner 50, two first gate trench portions 41, and the first mesa portion 61. The second gate trench portion 42 and the second mesa portion 62 also have a structure similar to that of the first gate trench portion 41 and the first mesa portion 61.

The structure of the semiconductor substrate 10 and the drain electrode 24 in the B-B cross section is the same as the structure in the A-A cross section illustrated in FIG. 2. In this example, the gate runner 50 is arranged above the interlayer dielectric film 38. As illustrated in FIG. 1, the gate runner 50 is provided above the plurality of first gate trench portions 41. The gate runner 50 is connected to the gate electrode 44 via a contact hole 56 provided in the interlayer dielectric film 38.

As illustrated in FIG. 3, the source region 12 and the base region 14 are also provided in the first mesa portion 61 at a position overlapping the gate runner 50. For this reason, a channel can also be formed in a region below the gate runner 50, and the channel density can be further improved.

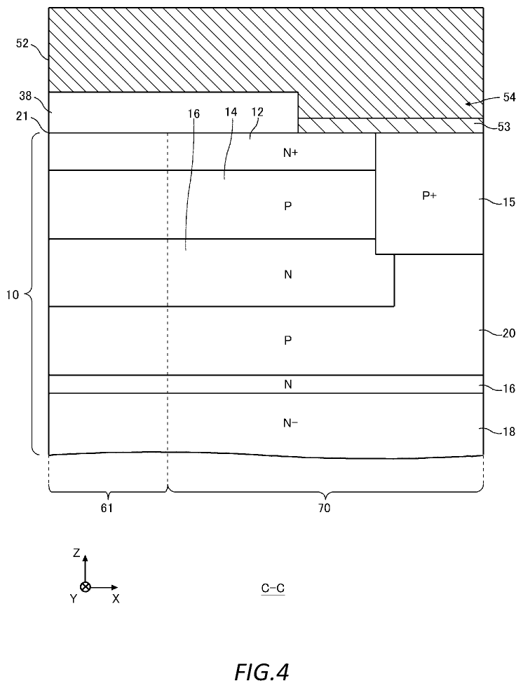

FIG. 4 is a view illustrating an example of a C-C cross section in FIG. 1. The C-C cross section is an XZ plane passing through the first mesa portion 61 and the mesa facing region 70. The second mesa portion 62 also has a structure similar to that of the first mesa portion 61. The structure of the first mesa portion 61 is similar to the structure described in FIGS. 2 and 3.

As illustrated in FIG. 4, the interlayer dielectric film 38 above the first mesa portion 61 is not provided with a contact hole for connecting the source electrode 52 to the first mesa portion 61. In FIG. 4, a part of the first mesa portion 61 is illustrated, but a contact hole is not provided in the interlayer dielectric film 38 in the entire first mesa portion 61. Accordingly, the first mesa portion 61 can be easily miniaturized.

The source region 12 extends from the first mesa portion 61 to the mesa facing region 70 in the X axis direction. The source region 12 of this example extends below the contact hole 54. The source region 12 is connected to the source electrode 52 via the contact hole 54. The source electrode 52 may be directly connected to the source region 12, or may be connected to the source region 12 via a contact electrode 53 as illustrated in FIG. 4. The contact electrode 53 is, for example, an electrode obtained by silicidation of the source electrode 52. The source region 12 may or may not be in contact with the contact region 15.

The base region 14 extends from the first mesa portion 61 to the mesa facing region 70 in the X axis direction. The source region 12 of this example extends to a position connected to the contact region 15. The source region 12 is connected to the source electrode 52 via the contact region 15 and the contact hole 54. The base region 14 of this example is not exposed to the upper surface 21 of the semiconductor substrate 10 in the first mesa portion 61. In the first mesa portion 61 of this example, the region of the P type such as the base region 14 or the contact region 15 is not exposed on the upper surface 21 of the semiconductor substrate 10. Only the source region 12 may be exposed on the upper surface of the first mesa portion 61. With such a structure, the first mesa portion 61 can be easily miniaturized. In addition, the source region 12 is arranged in a region in contact with the first gate trench portion 41 on the upper surface 21 of the semiconductor substrate 10. Accordingly, the channel density can be further improved.

The high concentration region 16 may extend from the first mesa portion 61 to the mesa facing region 70 in the X axis direction. The high concentration region 16 may extend to below the contact hole 54 or may not extend. The high concentration region 16 may be in contact with the drift region 18 at the first mesa portion 61. The high concentration region 16 in this example is connected to the base region 14 and the contact region 15.

The lower end region 20 may extend from the mesa facing region 70 to the first mesa portion 61 in the X axis direction. The lower end region 20 preferably covers at least the lower side of the contact region 15. The high concentration region 16 may extend to below the contact hole 54 or may not extend. The high concentration region 16 of this example is connected to the contact region 15.

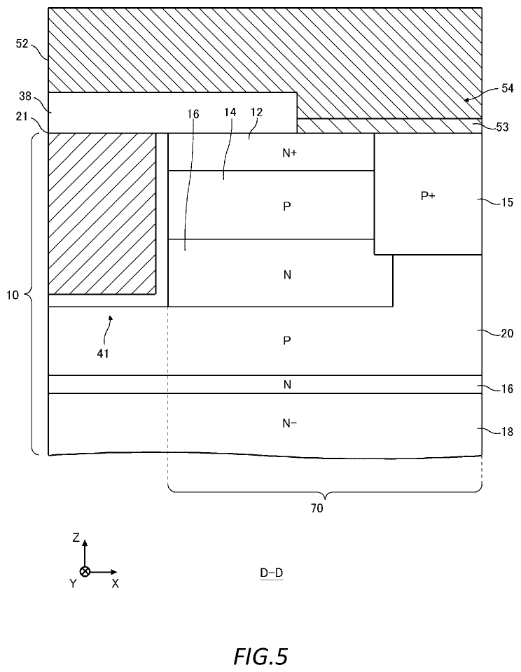

FIG. 5 is a view illustrating an example of a D-D cross section in FIG. 1. The D-D cross section is an XZ plane passing through the first gate trench portion 41 and the mesa facing region 70. The second gate trench portion 42 and the second mesa portion 62 also have a structure similar to that of the first gate trench portion 41 and the first mesa portion 61.

As illustrated in FIG. 5, the source region 12 and the base region 14 are also provided in the mesa facing region 70 in contact with the end portion of the first gate trench portion 41 in the X axis direction. The high concentration region 16 may also be provided in the mesa facing region 70 in contact with the end portion of the first gate trench portion 41 in the X axis direction. As described in FIG. 1, the source regions 12 and the base regions 14 of two first mesa portions 61 are connected to each other by extending along the end portions of the first gate trench portions 41 in the X axis direction. With such a structure, a channel can also be formed in the base region 14 in contact with the end portion of the first gate trench portion 41 in the X axis direction. For this reason, the channel density can be further improved.

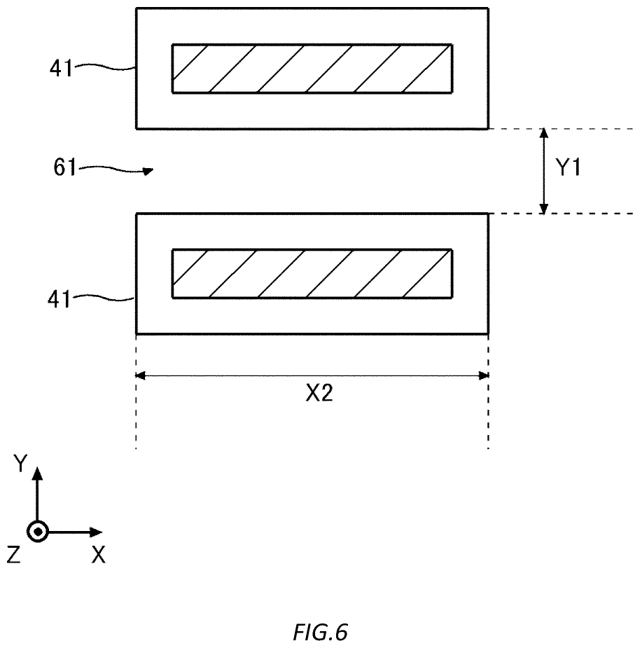

FIG. 6 is an enlarged top view of the first gate trench portion 41 and the first mesa portion 61. The second gate trench portion 42 and the second mesa portion 62 also have a structure similar to that of the first gate trench portion 41 and the first mesa portion 61.

Each of the first gate trench portions 41 may have a longer side in the X axis direction. That is, the length of each of the first gate trench portions 41 in the X axis direction may be larger than the width thereof in the Y axis direction. Each of the first mesa portions 61 may have a longer side in the X axis direction. That is, the length of each of the first mesa portions 61 in the X axis direction may be larger than the width thereof in the Y axis direction.

The respective lengths X2 of the first gate trench portions 41 in the X axis direction may be the same as each other. As an example, the length X2 of the first gate trench portion 41 in the X axis direction is 3 μm or more and 20 μm or less. The length X2 may be 5 μm or more, or 10 μm or more. The length X2 may be 15 μm or less, or may be 10 μm or less.

When the length X2 is small, the width of the channel in the X axis direction is shortened in one first mesa portion 61. For this reason, it is difficult to improve the channel density. In addition, when the length X2 is large, a distance between the center of the first mesa portion 61 and the contact hole 54 increases. For this reason, a path passing through the source region 12 from the center of the first mesa portion 61 to the contact hole 54 becomes long, and the electrical resistance of the path becomes large. For this reason, an on-resistance increases. In addition, a path passing through the base region 14 from the center of the first mesa portion 61 to the contact hole 54 becomes long, and the electrical resistance of the path becomes large. For this reason, it is difficult to pull out a hole from the first mesa portion 61 when the semiconductor device 100 is turned off, for example.

A distance between two first gate trench portions 41 adjacent to each other in the Y axis direction is referred to as Y1. That is, the width of the first mesa portion 61 in the Y axis direction is referred to as Y1. The distance Y1 may be shorter than the length X2 of the first gate trench portion 41. The distance Y1 may be ⅕ or less or 1/10 or less of the length X2. Since the contact hole 54 is provided in the mesa facing region 70, and the contact hole is not provided in the first mesa portion 61, the distance Y1 may be smaller than the distance X1 illustrated in FIG. 1. The distance Y1 may be a half or less or ¼ or less of the distance X1. The distance Y1 may be 2 μm or less, 1 μm or less, 0.5 μm or less, or 0.1 μm or less. The distance Y may have a lower limit value corresponding to the resolution of the manufacturing device. The distance Y1 may be 0.01 μm or more, 0.05 μm or more, or 0.1 μm or more.

The length X2 may be smaller or larger than the distance X1 illustrated in FIG. 1. The total length of the region where the channel region 71 is formed in the X axis direction may be larger than the total length of the region where the mesa facing region 70 is formed. Accordingly, the proportion occupied by the channel region 71 in the semiconductor substrate 10 can be further improved, and the channel density can be further improved. The total length of the region where the channel region 71 is formed in the X axis direction may be 2 times or more, 5 times or more, or 10 times or more the total length of the region where the mesa facing region 70 is formed.

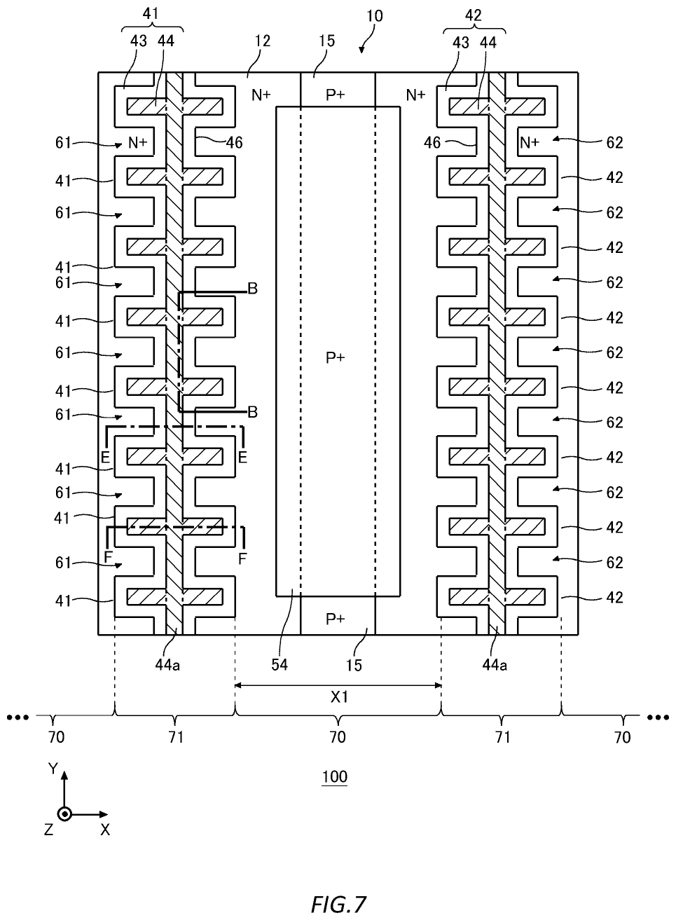

FIG. 7 is a top view illustrating a different example of the semiconductor device 100 according to one embodiment of the present invention. The semiconductor device 100 in FIG. 7 is different from the semiconductor device 100 in FIG. 1 in that the plurality of first gate trench portions 41 arranged side by side in the first direction (the Y axis direction in the example of FIG. 7) on the upper surface of the semiconductor substrate 10 are coupled in the Y axis direction. The respective intermediate portions of the first gate trench portions 41 in the X axis direction may be coupled in the Y axis direction. The middle in the X axis direction refers to a position between both ends of the first gate trench portion 41 in the X axis direction. The middle in the X axis direction may be the center of the first gate trench portion 41 in the X axis direction. In addition, the plurality of second gate trench portions 42 may also be coupled in the Y axis direction. In FIG. 7 and the like, a structure of a coupling portion 46 coupling the plurality of first gate trench portions 41 in the first direction will be described, but a coupling portion 46 coupling the plurality of second gate trench portions 42 also has a similar structure.

The coupling portion 46 coupling the plurality of first gate trench portions 41 has a structure similar to that of the first gate trench portion 41. That is, in the coupling portion 46, a trench is provided from the upper surface of the semiconductor substrate 10 to the inside of the semiconductor substrate 10, and the gate dielectric film 43 and a gate electrode 44a are provided in the trench. The coupling portion 46 extends in the Y axis direction and couples the plurality of first gate trench portions 41. The structures of the first mesa portion 61 and the mesa facing region 70 are the same as those in the example of FIG. 1. The gate electrode 44a may be formed of the same material as the gate electrode 44. The width of the coupling portion 46 in the X axis direction may be the same as or different from the width of the first gate trench portion 41 in the Y axis direction. The depth of the coupling portion 46 in the Z axis direction may be the same as or different from the depth of the first gate trench portion 41 in the Z axis direction.

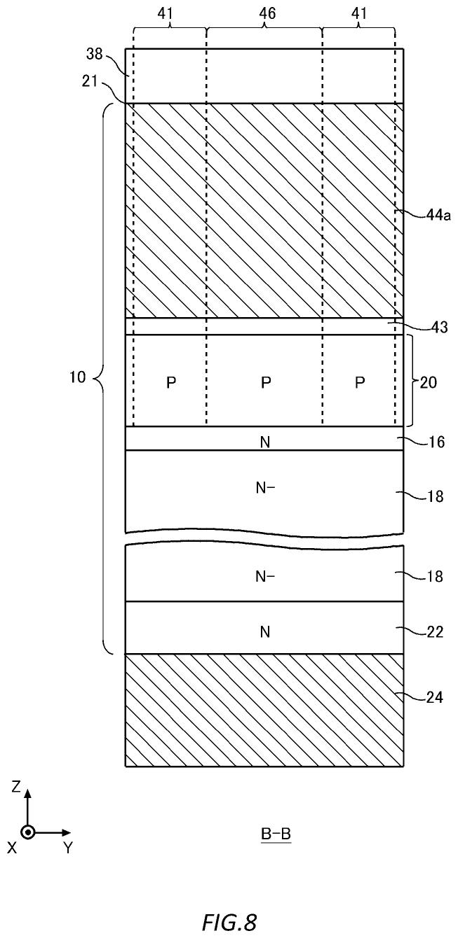

FIG. 8 is a view illustrating an example of a B-B cross section in FIG. 7. The B-B cross section is a YZ plane passing through two first gate trench portions 41 and the coupling portion 46. The second gate trench portion 42 and the second mesa portion 62 also have the same structure as the first gate trench portion 41 and the gate electrode 44a. The gate electrode 44a of the coupling portion 46 couples the gate electrodes 44 of the plurality of first gate trench portions 41. In FIG. 8, the gate electrode 44a and the gate electrode 44 are collectively referred to as the gate electrode 44a. The lower end region 20 of the P type in contact with the lower end of the gate electrode 44a via the gate dielectric film 43 may be provided.

In this example, no gate runner is arranged above the interlayer dielectric film 38. The gate electrode 44a coupling the plurality of gate electrodes 44 extends on the upper surface of the semiconductor substrate 10 at the end portion in the Y axis direction and is connected to a gate runner (not illustrated).

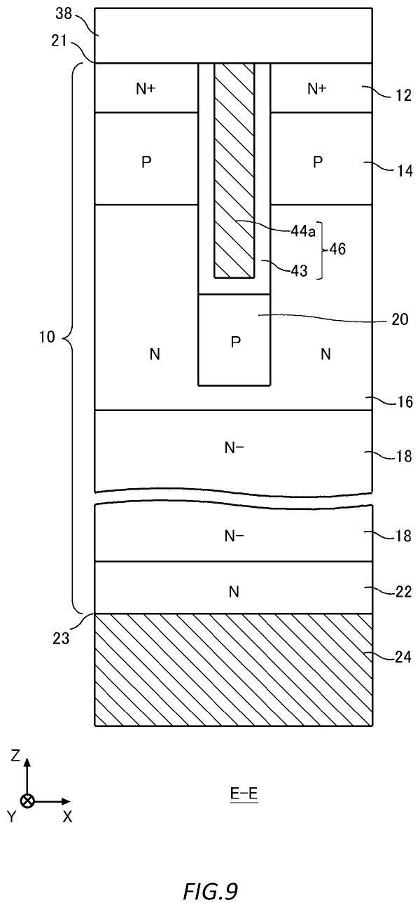

FIG. 9 is a view illustrating an example of an E-E cross section in FIG. 7. The E-E cross section is an XZ plane passing through the coupling portion 46 between two first gate trench portions 41. The second gate trench portion 42 and the second mesa portion 62 also have a structure similar to that of the first gate trench portion 41 and the first mesa portion 61. The source region 12 and the base region 14 are provided on both sides of the coupling portion 46 in the X axis direction. The high concentration region 16 covers the bottom portion of the first gate trench portion 41 and the lower end region 20 of the P type.

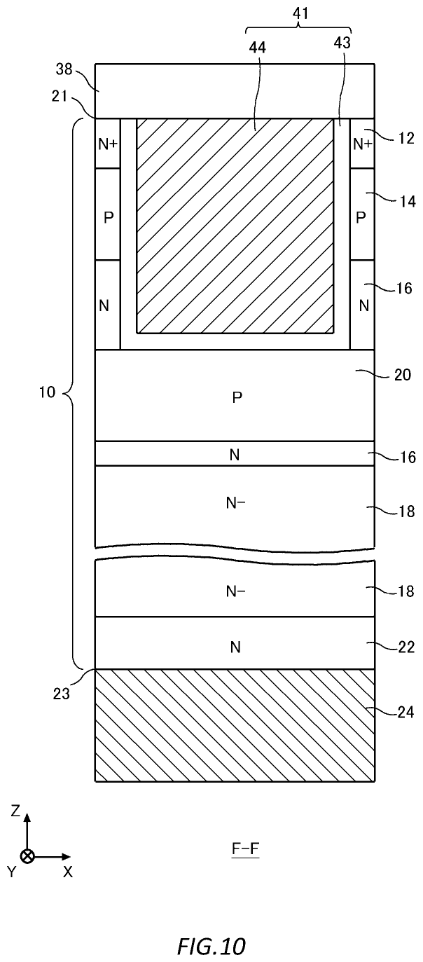

FIG. 10 is a view illustrating an example of an F-F cross section in FIG. 7. The F-F cross section is an XZ plane passing through the first gate trench portion 41. The second gate trench portion 42 and the second mesa portion 62 also have a structure similar to that of the first gate trench portion 41 and the first mesa portion 61.

The source regions 12, the base regions 14, and the high concentration regions 16 are provided on both sides of the first gate trench portion 41 in the X axis direction. The lower end region 20 is connected to the lower surfaces of the high concentration region 16 and the gate dielectric film 43. The plurality of first gate trench portions 41 are coupled by the gate electrode 44a, and the gate electrode 44 and the lower end region 20 in contact with the gate electrode 44a are also coupled. Since the plurality of lower end regions 20 are coupled, the coupled lower end region 20 may be connected to the contact region 15 at least at one location, and the lower end region 20 does not necessarily need to be provided below the high concentration region 16. In the example illustrated in FIGS. 8 to 10, since the gate electrode 44 is coupled by the gate electrode 44a, the channel density is reduced by the amount of the gate electrode 44a, but the gate runner can be reduced, and the degree of freedom in the arrangement of the gate runner and the source electrode is increased.

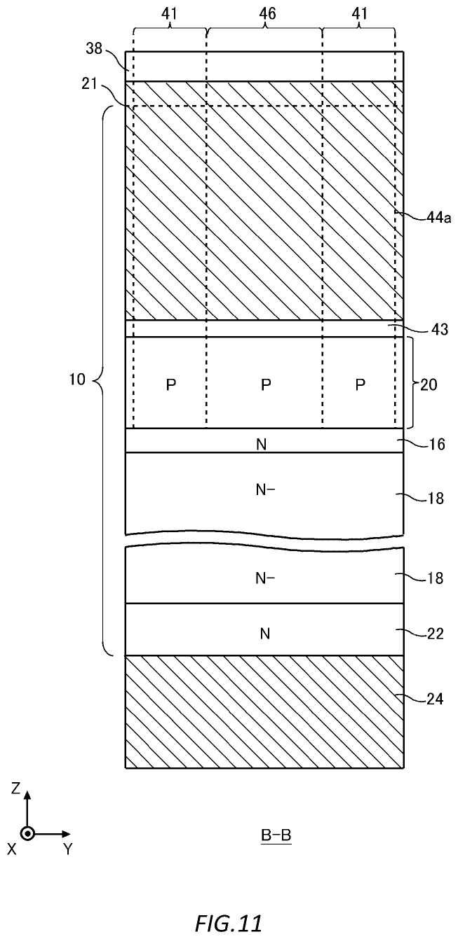

FIG. 11 is a view illustrating a different example of the B-B cross section in FIG. 7. The B-B cross section is a YZ plane passing through two first gate trench portions 41 and the coupling portion 46. The second gate trench portion 42 and the second mesa portion 62 also have the same structure as the first gate trench portion 41 and the gate electrode 44a. The gate electrode 44a of the coupling portion 46 couples the gate electrodes 44 of the plurality of first gate trench portions 41. In FIG. 11, the gate electrode 44a and the gate electrode 44 are collectively referred to as the gate electrode 44a. The lower end region 20 of the P type in contact with the lower end of the gate electrode 44a via the gate dielectric film 43 may be provided.

In this example, no gate runner is arranged above the interlayer dielectric film 38. The gate electrode 44a coupling the plurality of gate electrodes 44 extends on the upper surface of the semiconductor substrate 10 at the end portion in the Y axis direction and is connected to a gate runner (not illustrated). In contrast to one example of FIGS. 8 to 10 in which the gate dielectric film is formed in the trench, the gate electrode 44 of polysilicon is deposited on the gate dielectric film, and polysilicon is formed up to the upper surface 21 of the semiconductor substrate 10 by etch-back, in the different example of FIGS. 11 to 13, the etch-back amount of polysilicon is reduced, and polysilicon is left higher than the upper surface 21 of the semiconductor substrate 10.

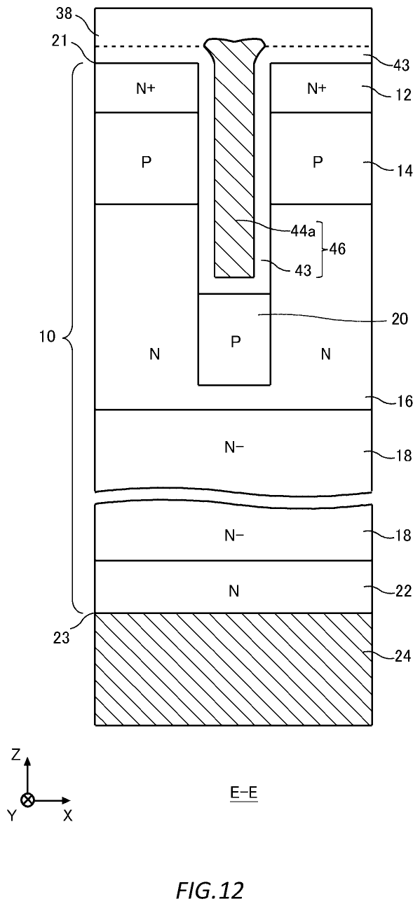

FIG. 12 is a view illustrating a different example of the E-E cross section in FIG. 7. The E-E cross section is an XZ plane passing through the coupling portion 46 between two first gate trench portions 41. The second gate trench portion 42 and the second mesa portion 62 also have a structure similar to that of the first gate trench portion 41 and the first mesa portion 61. The source region 12 and the base region 14 are provided on both sides of the coupling portion 46. The high concentration region 16 covers the bottom portion of the trench and the lower end region 20 of the P type.

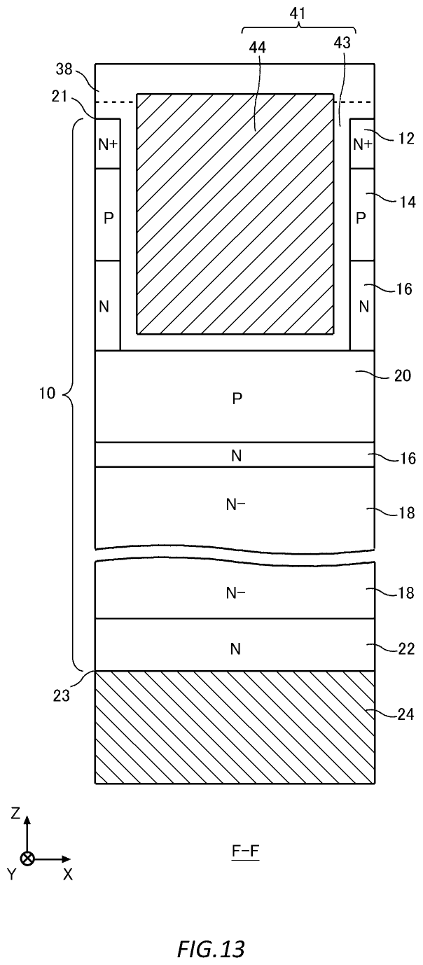

FIG. 13 is a view illustrating a different example of the F-F cross section in FIG. 7. The F-F cross section is an XZ plane passing through the first gate trench portion 41. The second gate trench portion 42 and the second mesa portion 62 also have a structure similar to that of the first gate trench portion 41 and the first mesa portion 61.

The source regions 12, the base regions 14, and the high concentration regions 16 are provided on both sides of the first gate trench portion 41. The lower end region 20 is connected to the lower surfaces of the high concentration region 16 and the gate dielectric film 43. The plurality of first gate trench portions 41 are coupled by the gate electrode 44a, and the gate electrode 44 and the lower end region 20 in contact with the gate electrode 44a are also coupled. Since the plurality of lower end regions 20 are coupled, the coupled lower end region 20 may be connected to the contact region 15 at least at one location, and the lower end region does not necessarily need to be provided below the high concentration region 16. In the example of FIGS. 11 to 13, since the gate electrode 44 and the gate electrode 44a are formed higher than the upper surface 21 of the semiconductor substrate 10, the wiring resistance of the gate can be made lower than that in the example of FIGS. 8 to 10.

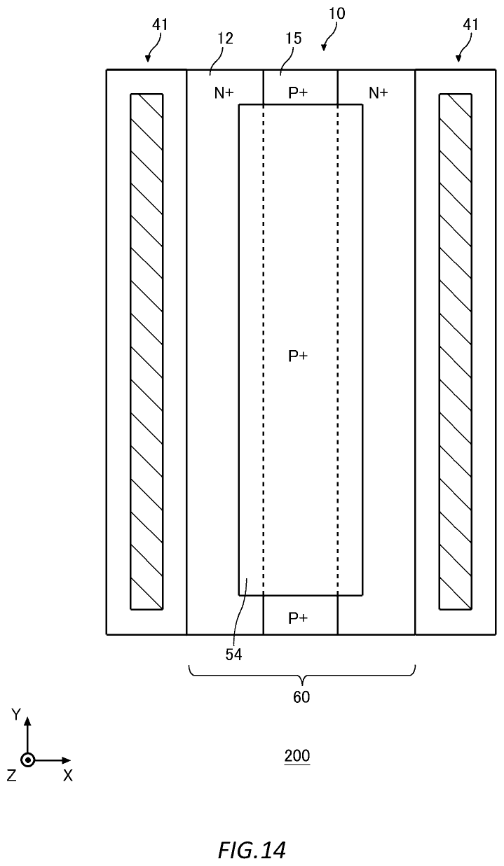

FIG. 14 is a top view illustrating a semiconductor device 200 according to a comparative example. In the semiconductor device 200, the contact hole 54 is provided in the mesa portion 60 between two first gate trench portions 41. The source region 12 and the contact region 15 are exposed on the upper surface of the mesa portion 60. The contact hole 54 connects the source region 12 and the contact region 15 to the source electrode 52.

When the contact hole 54 exposes the first gate trench portion 41 (particularly, the gate electrode 44), the source electrode 52 and the gate electrode 44 are connected. For this reason, in the comparative example, the contact hole 54 is arranged away from the first gate trench portion 41 in consideration of the resolution, mask deviation, or the like of the manufacturing device. Therefore, the width of the mesa portion 60 in the X axis direction is limited by the resolution of the manufacturing device or the like, and it is difficult to miniaturize the mesa portion 60.

According to the example described in FIGS. 1 to 13, since the contact hole 54 is not formed with respect to the first mesa portion 61, the first mesa portion 61 can be easily miniaturized. For this reason, the channel density can be improved.

While the present invention has been described by way of the embodiments, the technical scope of the present invention is not limited to the above described embodiments. It is apparent to persons skilled in the art that various alterations or improvements can be made to the above described embodiments. It is also apparent from the description of the claims that embodiments added with such alterations or improvements can be included in the technical scope of the present invention.

What is claimed is:

1. A semiconductor device comprising:
a semiconductor substrate which has an upper surface and a lower surface, has a drift region of a first conductivity type between the upper surface and the lower surface, and contains silicon carbide;
a plurality of first gate trench portions which are provided from the upper surface of the semiconductor substrate to an inside of the semiconductor substrate and arranged side by side on the upper surface of the semiconductor substrate in a first direction;
a first mesa portion which is sandwiched between two of the first gate trench portions in the first direction;
a mesa facing region which is not sandwiched between two of the first gate trench portions in the first direction and is arranged to face the first mesa portion in a second direction different from the first direction;
a source region of the first conductivity type which is provided in the first mesa portion, is arranged between the upper surface of the semiconductor substrate and the drift region, and has a doping concentration higher than that of the drift region;
an interlayer dielectric film which is provided above the upper surface of the semiconductor substrate;
an upper-surface electrode which is provided above the interlayer dielectric film; and
a contact hole which is provided in the interlayer dielectric film in the mesa facing region and connects the upper-surface electrode and the upper surface of the semiconductor substrate, wherein
the contact hole is not provided in the interlayer dielectric film above the first mesa portion, and
the source region is provided to extend from the first mesa portion to the mesa facing region and is connected to the upper-surface electrode via the contact hole.

2. The semiconductor device according to claim 1, comprising
a plurality of first mesa portions including the first mesa portion, wherein
the source regions of the plurality of the first mesa portions are connected to each other in the mesa facing region.

3. The semiconductor device according to claim 2, wherein
the contact hole is arranged to face the plurality of the first mesa portions in the second direction.

4. The semiconductor device according to claim 3, wherein
the contact hole has a longer side in the first direction.

5. The semiconductor device according to claim 1, further comprising
a base region of a second conductivity type which is provided in the first mesa portion and arranged between the source region and the drift region, wherein
the base region is provided to extend from the first mesa portion to the mesa facing region, and is connected to the upper-surface electrode via the contact hole.

6. The semiconductor device according to claim 5, wherein
the base region is not exposed to the upper surface of the semiconductor substrate in the first mesa portion.

7. The semiconductor device according to claim 1, wherein
each of the first gate trench portions has a longer side in the second direction.

8. The semiconductor device according to claim 7, wherein
a length of each of the first gate trench portions in the second direction is 3 μm or more and 20 μm or less.

9. The semiconductor device according to claim 7, wherein
a distance between two of the first gate trench portions adjacent to each other in the first direction is shorter than a length of the first gate trench portion in the second direction.

10. The semiconductor device according to claim 1, wherein
the plurality of first gate trench portions are separated from each other.

11. The semiconductor device according to claim 1, further comprising
a gate runner which is provided above the upper surface of the semiconductor substrate to overlap the plurality of first gate trench portions and connected to the plurality of first gate trench portions.

12. The semiconductor device according to claim 11, wherein
the source region is also provided at a position overlapping the gate runner in the first mesa portion.

13. The semiconductor device according to claim 1, further comprising
a plurality of second gate trench portions which are provided from the upper surface of the semiconductor substrate to the inside of the semiconductor substrate, arranged side by side on the upper surface of the semiconductor substrate in the first direction, and arranged to face the plurality of first gate trench portions in the second direction, wherein
the mesa facing region is arranged between the plurality of first gate trench portions and the plurality of second gate trench portions.

14. The semiconductor device according to claim 13, further comprising
a second mesa portion which is sandwiched between two of the second gate trench portions in the first direction, wherein
the second mesa portion has the source region,
the contact hole is not provided in the interlayer dielectric film in the second mesa portion, and
the source region of the second mesa portion is provided to extend from the second mesa portion to the mesa facing region, and is connected to the upper-surface electrode via the contact hole.

15. The semiconductor device according to claim 13, wherein
a distance between two of the first gate trench portions adjacent to each other in the first direction is shorter than a distance between the plurality of first gate trench portions and the plurality of second gate trench portions in the second direction.

16. The semiconductor device according to claim 13, wherein
a distance between the plurality of first gate trench portions and the plurality of second gate trench portions in the second direction is 2 μm or less.

17. A semiconductor device comprising:
a semiconductor substrate which has an upper surface and a lower surface, has a drift region of a first conductivity type between the upper surface and the lower surface, and contains silicon carbide;
a plurality of first gate trench portions which are provided from the upper surface of the semiconductor substrate to an inside of the semiconductor substrate and arranged side by side on the upper surface of the semiconductor substrate in a first direction;
a first mesa portion which is sandwiched between two of the first gate trench portions in the first direction;
a mesa facing region which is not sandwiched between two of the first gate trench portions in the first direction and is arranged to face the first mesa portion in a second direction different from the first direction;
a source region of the first conductivity type which is provided in the first mesa portion, is arranged between the upper surface of the semiconductor substrate and the drift region, and has a doping concentration higher than that of the drift region;
an interlayer dielectric film which is provided above the upper surface of the semiconductor substrate;
an upper-surface electrode which is provided above the interlayer dielectric film; and
a contact hole which is provided in the interlayer dielectric film in the mesa facing region and connects the upper-surface electrode and the upper surface of the semiconductor substrate, wherein
the contact hole is not provided in the interlayer dielectric film above the first mesa portion, and
the first gate trench portions have longer sides in the second direction, respectively,
the semiconductor device further comprising
a coupling portion which couples respective middles of the longer sides of the first gate trench portions in the first direction.

18. The semiconductor device according to claim 17, wherein
the coupling portion includes a gate dielectric film and a gate electrode.

19. The semiconductor device according to claim 2, further comprising
a plurality of second gate trench portions which are provided from the upper surface of the semiconductor substrate to the inside of the semiconductor substrate, arranged side by side on the upper surface of the semiconductor substrate in the first direction, and arranged to face the plurality of first gate trench portions in the second direction, wherein
the mesa facing region is arranged between the plurality of first gate trench portions and the plurality of second gate trench portions.

20. The semiconductor device according to claim 3, further comprising
a plurality of second gate trench portions which are provided from the upper surface of the semiconductor substrate to the inside of the semiconductor substrate, arranged side by side on the upper surface of the semiconductor substrate in the first direction, and arranged to face the plurality of first gate trench portions in the second direction, wherein
the mesa facing region is arranged between the plurality of first gate trench portions and the plurality of second gate trench portions.
